(19) United States
(12) Patent Application Publication
(10) Pub. No.: US 2007/0068701 A1
(43) Pub. Date: Mar. 29, 2007

(54) Air trapped circuit board test pad via

(75) Inventors: Chee Kiong Fong, Cupertino, CA (US); Harjit Singh, Redmond, WA (US); Jelena H. Larsen, Los Gatos, CA (US); Raul Rodriguez-Montanez, Sammamish, WA (US); Rodney J. Amen, San Jose, CA (US)

Correspondence Address: WOODCOCK WASHBURN LLP (MICROSOFT CORPORATION), CIRA CENTRE, 12TH FLOOR, 2929 ARCH STREET, PHILADELPHIA, PA, 19104-2891, US

(73) Assignee: Microsoft Corporation, Redmond, WA (US)

(21) Appl. No.: 11/235,728

(22) Filed: Sep. 26, 2005

(51) Int. Cl. H05K 1/11; H01R 12/04

(52) U.S. Cl. 174/262

(57) ABSTRACT

A circuit board with vias that are suitable for use as test pads can be made according to a method whereby a first end of a via is blocked prior to heating solder paste that covers the opposite end of the via. As a result, air is trapped in the via when the solder paste is heated, which prevents melted solder paste from flowing in. Instead, the solder paste forms a dome shaped test pad over the via, which facilitates contact with the test probe. When applied to OSP circuit boards, the result is an OSP board with at least via that has a blocking material at one end and a solder dome over the opposite end.

### BACKGROUND

Circuit boards are made of several layers. One or more of the layers may be a surface finish. The surface finish was historically made of a lead-based material. Lead is now banned from many consumer products for environmental and public health reasons, so we must find other materials to use as a surface finish.

Modem surface finish materials include Organic Surface Protectant (OSP), immersion tin, immersion silver, electroless nickel/immersion gold, and gold direct on the copper. Each has benefits and potential weaknesses.

Circuit boards are tested before being incorporated into products. Testing a circuit board involves bringing a test probe into electrical contact with test pads on the circuit board. The density of modem chips, traces, and vias is so high that it is advantageous to use vias as test pads.

Bringing a test probe into electrical contact with a via presents the difficulty of ensuring a good electrical connection between the via and the probe. Vias are typically made of copper. Copper has a yield strength much higher than that of solder. Because copper is a hard surface compared to solder, it cannot absorb much energy from probing, resulting in a smaller effective contact area for the probe. The chances of successful electrical connections between test probes and unsoldered copper test pads are thus much less than the chances of successful electrical connections between test probes and soldered test pads. While test probes cannot effectively probe a copper surface directly, they can probe solder that is appropriately positioned atop a copper surface. Thus, if left unsoldered, a circuit board, e.g. a board with an OSP surface finish, will have difficulty establishing electrical connections during testing. To apply solder to a test pad, solder paste is applied on the test pad, and the circuit board is heated in an oven re-flow process. The solder paste melts, and then solidifies to form a layer of solder on the test pad.

Unfortunately, modem surface finishes, especially OSPs, make it difficult to use vias as test pads. The solder from the solder paste applied on the test pads will flow into the vias during the reflow process. When the solder from the test pads flows into the vias, the test pads will expose the copper, or only a small amount of solder. As a result, the exposed copper and/or solder pad height is too low, making it difficult for test probes to make electrical contact with via test pads. This difficulty translates into non-use of vias as test pads in lead free circuit boards, because the number of false negatives in circuit board testing would be too high.

In light of the foregoing, there is a need in the industry for improved techniques to allow the use of circuit board vias as test pads.

### SUMMARY

In consideration of the above-identified difficulties in the art, the present invention provides a substantially lead free circuit board with vias that are suitable for use as test pads, and methods of manufacturing such circuit boards. A first end of a via may be blocked, for example by applying soldermask over the via during soldermask application. As a result, air is trapped in the via when the circuit board is heated, which prevents melted solder paste from flowing in. Instead, the solder paste forms a dome shaped test pad over the via, which facilitates contact with the test probe. When this technique is used on an OSP circuit board, the result is an OSP board with at least one via, where the via has a blocking material at one end and a solder dome over the opposite end. Other features and advantages of the invention are described below.

### DRAWINGS

Lead free circuit boards with vias that are suitable for use as test pads, and methods of manufacturing such circuit boards in accordance with the present invention are further described with reference to the accompanying drawings in which:

FIG. 1 illustrates a process for blocking a first end of a via, applying solder paste to the opposite end, then heating the solder paste to form a test pad.

FIG. 2 illustrates a circuit board with a via, wherein the via is blocked at a first end and solder paste is applied to the opposite end.

FIG. 3 illustrates a circuit board with soldermask applied to cover various areas, including some vias. The areas to be covered with soldermask may be indicated in a circuit board design application User Interface (UI).

FIG. 4 illustrates a side view of a circuit board with a soldermask blocking material at a first end of a standard sized via and a dome shaped test pad at the opposite end of the via for making electrical connection with a test probe.

FIG. 5 illustrates a cross sectional view of a circuit board via that has not had a blocking material inserted into a first end prior to melting solder paste over the opposite end. The solder has run into the via and solidified without forming a dome shaped test pad over the via.

FIG. 6 illustrates a cross-sectional view of a circuit board via that had a first end covered with soldermask as a blocking material prior to melting solder paste over the opposite end. The solder has solidified into a dome-shaped test pad over the via that will easily make electrical connection with a test probe.

### DETAILED DESCRIPTION

Certain specific details are set forth in the following description and figures to provide a thorough understanding of various embodiments of the invention. Certain well-known details often associated with circuit board manufacture technology are not set forth in the following disclosure, however, to avoid unnecessarily obscuring the various embodiments of the invention. Further, those of ordinary skill in the relevant art will understand that they can practice other embodiments of the invention without one or more of the details described below. Finally, while various methods are described with reference to steps and sequences in the following disclosure, the description as such is for providing a clear implementation of embodiments of the invention, and the steps and sequences of steps should not be taken as required to practice this invention.

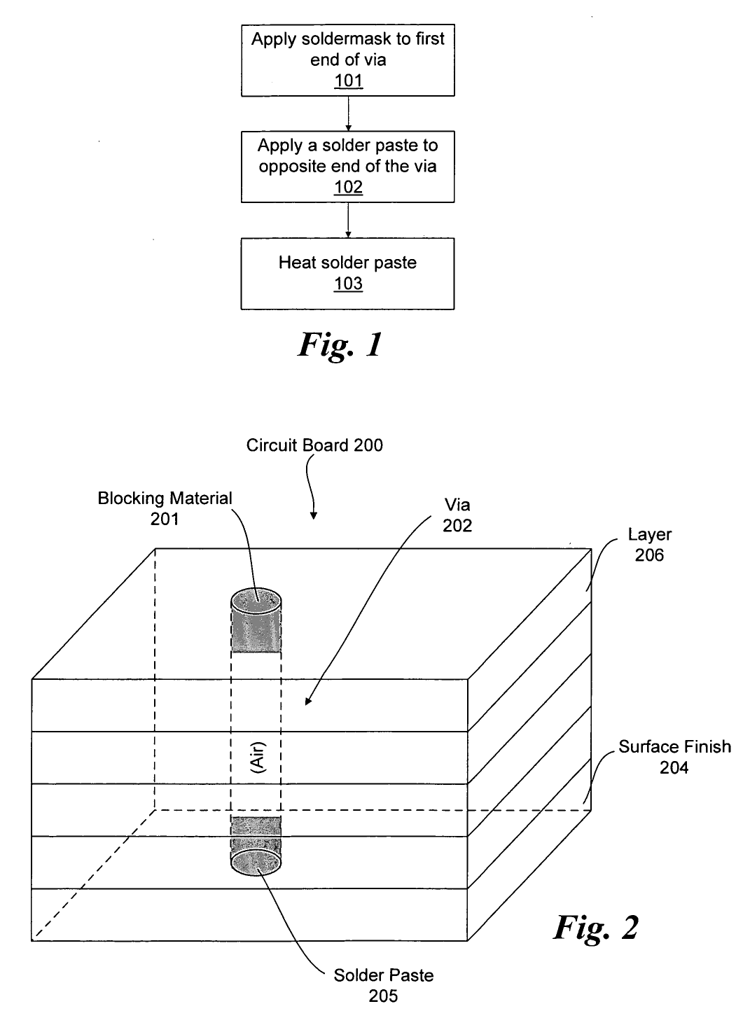

FIG. 1 teaches steps that can be performed when manufacturing a circuit board. When applying soldermask, instead of leaving an end of a via open and without any soldermask covering it, soldermask is applied over the via 101. Soldermask may be applied over a first end of all vias on a circuit board, or the application may be limited to only those vias that will be used to test the circuit board.

Next, when applying solder paste to those portions of the circuit board that will be used as test pads, solder paste may be applied to the opposite end of the via 102. Such application generally results in a configuration such as that illustrated in FIG. 2. Via 202 has a blocking material soldermask 201 covering a first end, and a solder paste 205 covering the opposite end. Air may be in the via 202 between blocking material 201 and solder paste 205.

Finally, with reference to FIG. 1, the solder paste may be heated 103. Heating the paste causes it to melt, then solidify into a solid test pad. Heating the solder paste may be pursuant to heating the entire circuit board in a reflow oven.

The steps of FIG. 1 are modifications of a larger process for manufacturing circuit boards. This manufacturing process is known in the art and need not be repeated herein, as it will be known to those of skill in the art. The manufacturing process often entails manufacture of a circuit board by a first company or department at a first location, then subsequent fixing of chips on the board by another company or department. The techniques explained herein may be carried out at any time during the manufacturing process, as convenient.

FIG. 2 provides a cross-sectional view of a circuit board 200 with a blocking material 201 covering a first end of a via 202. The blocking material 201 is conveniently a soldermask, although it could also be any other material that serves the purpose of blocking airflow out of the first end of the via 202. By blocking airflow, blocking material 201, along with air in via 202, prevents solder paste 205 from running into via 202 when solder paste 205 melts.

FIG. 2 also demonstrates that circuit board 200 is made of a number of layers. Different circuit boards have differing numbers of layers. A via 202 is a hole through some or all of those layers. One or more layers may be a surface finish 204. Surface finish may be one or both sides circuit board 200. Thus, in one embodiment, layer 206 may also be a surface finish layer.

In one embodiment, the invention is practiced in conjunction with OSP circuit board manufacture, in which an OSP is used as surface finish 204. There are a variety of compounds known in the art that qualify as OSP. Any such compound now in use or later developed is considered an OSP for the purposes of this disclosure.

OSP is a surface finish that has the advantage of being lead free or substantially lead free. The term substantially lead free as used herein means sufficiently lead free to qualify, under the laws and regulations of the United States, for distribution in consumer electronics products. Materials that are substantially lead free in circuit board 200 may be, for example, the surface finish 204, the solder paste 205, and the blocking material 201.

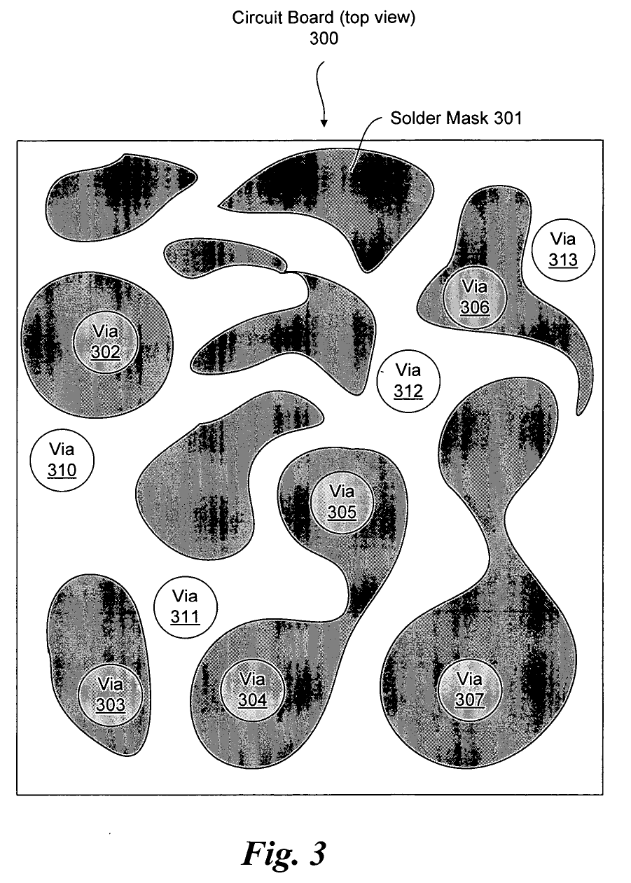

FIG. 3 illustrates a simplified exemplary top view of a circuit board 300. The dark grey and light grey areas are covered with soldermask 301. The white areas are not covered with soldermask. Thus, the light grey vias 302-307 are covered with soldermask 301. The white vias 310-313 are not covered with soldermask 301.

Soldermask 301 is generally applied to circuit board 300 to prevent solder from sticking to those areas covered with soldermask 301. In accordance with the techniques presented herein, soldermask 301 may also be applied to vias 302-307 for the purpose of facilitating use of the vias 302-307 to test the circuit board 300. By covering vias 302-307 with soldermask 301, air is prevented from escaping out the covered end of the vias. As a result, solder paste applied to the opposite end of vias 202-307 will not run as far into vias 302-307 as it otherwise would when melted. Instead, the solder paste will form a good test pad.

Soldermask 301 need not be applied to all vias on a circuit board 300. For this reason, vias 310-313 are illustrated as not covered with soldermask 301. A decision not to cover vias 310-313 with soldermask 301 may be made, for example, because vias 310-313 will not be used to test the circuit board 300.

As illustrated, soldermask 301 may be applied to many portions of circuit board 300 that may not coincide with a via. Soldermask may be applied to vias 302-307 at the same time that soldermask is applied to other, non-via areas of the circuit board 300. This provides the benefit of streamlining soldermask application as it may be applied both for its general purpose and for the purpose of via blockage at the same time. There are a variety of compounds that may be used as soldermask, any of which are appropriate for use as a blocking material.

Decisions concerning what areas to cover with solder mask are made at the circuit board design stage, using software that presents an image of a circuit board to a designer. A User Interface (UI) may be presented to the designer, allowing him to set various properties of a circuit board. One such property is which areas to cover with soldermask 301. Thus the designer may indicate in a circuit board design application that a via is to be covered with soldermask 301. For example, a representation such as FIG. 3 may be presented to a designer, and he may have the power to cover or uncover any portion of circuit board 300. Manufacturing equipment is subsequently configured to produce circuit boards according to the design.

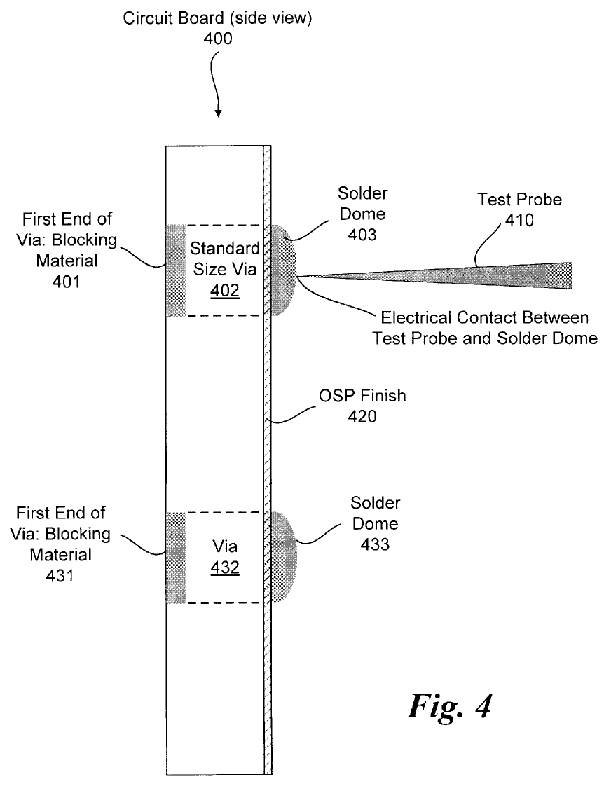

FIG. 4 illustrates a circuit board 400 that is a product of the manufacturing techniques described above. The illustrated circuit board 400 has an OSP surface finish 420, and may further incorporate substantially lead free elements such as lead free solder. Note that while vias 402 and 403 are oriented in the same direction in FIG. 4, this is not required. In modem circuit boards, it is possible to have chips fastened to both sides of the board, and it is possible to use test pads oriented on either side of a circuit board. Thus, in some embodiments, one or more vias such as 432 may instead be oriented in the opposite direction, in which case the solder dome 433 would instead be on a side of the circuit board 400 opposite to that of solder dome 403. Therefore, when the language such as “a first end of a via” is used herein, it should be recognized that the “first end” need not necessarily be on the same side of a circuit board as all other “first ends”. The first end of a via is defined herein as the end that is blocked using a blocking material.

Vias 402 and 432 are standard size vias. The dimensions of standard size vias are known in the art, and should the size change, the invention may be used with any other size via as well. Today, standard size vias are generally between 8 and 20 mil. Micro-vias are substantially smaller than standard size vias. The term “standard size via” as used herein specifically excludes micro-vias.

FIG. 4 illustrates a blocking material 401 and 431 covering a first end of vias 402 and 432. The light area between 401 and 403 can be air. Note that while some air in a via may be a byproduct of blocking a first end of the via, the presence of air in a via is not required to practice the invention. Some mixture of gasses not considered to be “air” may be used, or some other substance, such as additional soldermask or solder paste, may be used to fill via 402 or 432 instead of air.

Solder dome 403 and 433 is the solder test pad that is created by melting solder paste that is initially applied to the opposite end of the via 402 and 432. The term “dome” as used herein refers to a convex curvature that extends away from the circuit board 400 as illustrated in FIG. 4. Solder domes 402 and 432 are test pads capable of making an electrical connection between the vias 402 and 432 and a test probe 410. Note that a variety of solder pastes are available, and it will be appreciated that any solder paste can be used in embodiments of the invention.

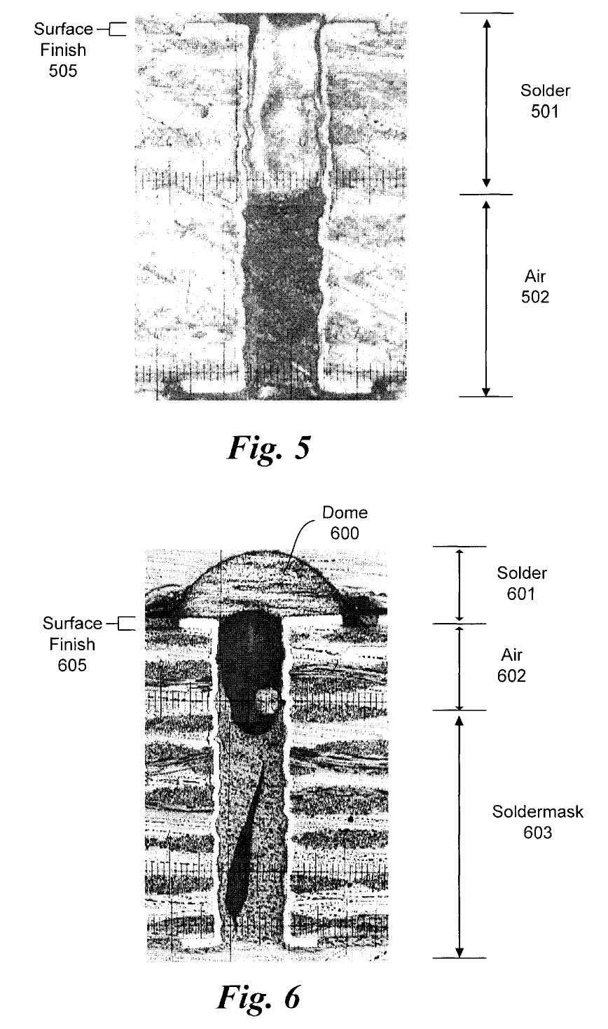

FIGS. 5 and 6 provide cross-sectional photographs of actual circuit board vias. FIG. 5 demonstrates the problem of solder paste melting and running into a via. Solder 501 has solidified within the via, instead of forming a dome over the via. Air 502 is not blocked from leaving the bottom of the depicted via.

FIG. 6 illustrates the sharply contrasting results that may be obtained when a blocking material such as soldermask 603 prevents air 602 from escaping the via. The melted solder paste solidified into a nicely shaped dome 600 over the via. Dome 600 will provide a superior electrical connection for a test probe.

In addition to the specific implementations explicitly set forth herein, other aspects and implementations will be apparent to those skilled in the art from consideration of the specification disclosed herein. It is intended that the specification and illustrated implementations be considered as examples only, with a true scope and spirit of the following claims.

1-12. (canceled)

13. A substantially lead free circuit board comprising:
an Organic Surface Protection (OSP) surface finish;
at least one via running through said OSP surface finish;
a blocking material situated at a first end of said via;
a test pad made from a material consisting of substantially lead free solder paste, said test pad situated over an opposite end of said via.

14. The substantially lead free circuit board of claim 13 wherein said blocking material is a soldermask.

15. The substantially lead free circuit board of claim 14 wherein said soldermask is applied during a procedure for preventing solder from sticking to areas covered with soldermask.

16. The substantially lead free circuit board of claim 13, further comprising an air pocket situated within said via between said blocking material and said test pad.

17. The substantially lead free circuit board of claim 13 wherein said test pad provides an electrical connection to said via.

18. The substantially lead free circuit board of claim 17 wherein said test pad provides a contact point for a test probe used in testing said substantially lead free circuit board.

19. The substantially lead free circuit board of claim 13 wherein said at least one via is a standard size via.

20. The substantially lead free circuit board of claim 13 wherein said at least one via comprises substantially all vias on the substantially lead free circuit board that are to be used as test pads.
